(19) United States
(12) Patent Application Publication
(10) Pub. No.: US 2007/0126358 A1
(43) Pub. Date: Jun. 7, 2007

(54) ORGANIC EL DISPLAY

(76) Inventors: Satoshi OKUTANI, Ishikawa-gun (JP); Hiroshi Sano, Hakusan-shi (JP); Kazuyuki Sunohara, Kanazawa-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/670,004

(22) Filed: Feb. 1, 2007

Related U.S. Application Data
(63) Continuation of application No. PCT/JP05/17229, filed on Sep. 13, 2005.

(30) Foreign Application Priority Data
Sep. 27, 2004 (JP) 2004-279872

(51) Int. Cl. H05B 33/04; H01J 1/62

(52) U.S. Cl. 313/512

(57) ABSTRACT

A top emission organic EL display includes an array substrate including an insulating substrate, organic EL elements which are arranged on a main surface of the insulating substrate, and an outcoupling layer which extracts light components propagating in in-plane direction while causing multiple-beam interference from the organic EL element to make the light components travel in front of the organic EL element, and a sealing substrate facing and spaced apart from the organic EL elements. The display forms an enclosed space filled with an inert gas or evacuated between the sealing substrate and an element portion of the array substrate corresponding to the organic EL element. A distance between the element portion and the sealing substrate is 100 nm or longer.

### CROSS-REFERENCE TO RELATED APPLICATIONS

This is a Continuation Application of PCT Application No. PCT/JP2005/017229, filed Sep. 13, 2005, which was published under PCT Article 21(2) in Japanese.

This application is based upon and claims the benefit of priority from prior Japanese Patent Application No. 2004-279872, filed Sep. 27, 2004, the entire contents of which are incorporated herein by reference.

### BACKGROUND OF THE INVENTION

1. Field of the Invention

The present invention relates to an organic electroluminescent (EL) display.

2. Description of the Related Art

Since organic EL displays are of self-emission type, they have a wide viewing angle and a high repose speed. In addition, they do not require a backlight, and therefore, low-profile and lightweight are possible. For these reasons, the organic EL displays are attracting attention as a display which substitutes the liquid crystal display.

An organic EL element, which is the main part of the organic EL displays, includes a light-transmitting front electrode, a light-reflecting or light-transmitting back electrode facing the front electrode, and an organic layer interposed between the electrodes and containing a light-emitting layer. The organic EL element is a charge-injection type light-emitting element which emits light when an electric current flows through the organic layer.

In the meantime, the luminance of the organic EL element increases with the magnitude of current flowing through the EL element. However, if the current density is increased, power consumption increases and the lifetime of the organic EL element is significantly reduced. Therefore, in order to achieve high luminance, low power consumption, and long lifetime, it is important to more efficiently extract the light emitted by the organic element from the organic EL display, i.e., to improve an outcoupling efficiency.

### BRIEF SUMMARY OF THE INVENTION

An object of the present invention is to improve an outcoupling efficiency of an organic EL display.

According to an aspect of the present invention, there is provided a top emission organic EL display comprising an array substrate comprising an insulating substrate, organic EL elements which are arranged on a main surface of the insulating substrate, and an outcoupling layer which extracts light components propagating in in-plane direction while causing multiple-beam interference from the organic EL element to make the light components travel in front of the organic EL element, and a sealing substrate facing and spaced apart from the organic EL elements, wherein the display forms an enclosed space filled with an inert gas or evacuated between the sealing substrate and an element portion of the array substrate corresponding to the organic EL element, and wherein a distance between the element portion and the sealing substrate is 100 nm or longer.

### BRIEF DESCRIPTION OF THE SEVERAL VIEWS OF THE DRAWING

FIG. 1 is a sectional view schematically showing an organic EL display according to a first embodiment of the present invention;

FIG. 2 is a partial cross section showing an enlarged view of the organic EL display shown in FIG. 1;

FIG. 3 is a graph showing an example of a relationship between a refractive index of a waveguide layer and an evanescent wave penetration depth;

FIG. 4 is a partial cross section schematically showing an organic EL display according to a second embodiment of the present invention;

FIG. 5 is a sectional view schematically showing an example of an outcoupling layer which can be used in the organic EL display of FIG. 4;

FIG. 6 is a sectional view schematically showing an example of an outcoupling layer which can be used in the organic EL display of FIG. 4;

FIG. 7 is a sectional view schematically showing an example of an outcoupling layer which can be used in the organic EL display of FIG. 4;

FIG. 8 is a sectional view schematically showing an example of an outcoupling layer which can be used in the organic EL display of FIG. 4; and

FIG. 9 is a sectional view schematically showing an example of an outcoupling layer which can be used in the organic EL display of FIG. 4.

### DETAILED DESCRIPTION OF THE INVENTION

Embodiments of the present invention will be described below in detail with reference to the accompanying drawings. The same reference numerals denote the same or similar constituent elements throughout the drawings, and a repetitive description thereof will be omitted.

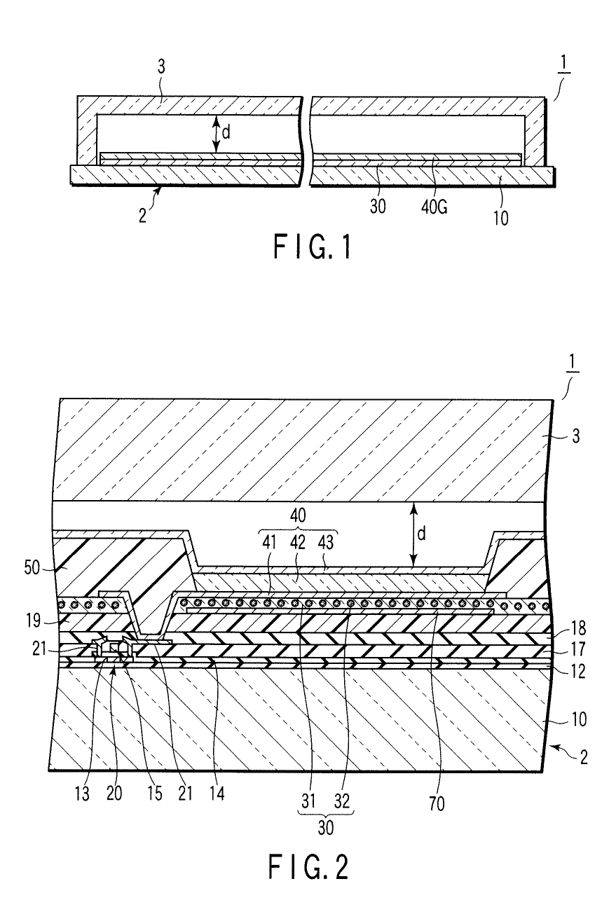

FIG. 1 is a cross sectional view schematically showing an organic EL display according to a first embodiment of the present invention. FIG. 2 is a partial cross section showing an enlarged view of the organic EL display shown in FIG. 1. In FIGS. 1 and 2, the organic EL display 1 is illustrated such that its display surface, that is, the front surface, faces upwardly and the back surface faces downwardly.

The organic EL display 1 is a top emission organic EL display which employs an active matrix drive method. The organic EL display 1 includes an array substrate 2 and a sealing substrate 3.

For example, a surface of the sealing substrate 3 on the side of the array substrate 2 has a recessed shape. The array substrate 2 and the sealing substrate are joined together at peripheries thereof by means of, for example, adhesive or frit seal so as to form an enclosed space therebetween. The enclosed space is airtight and may be filled with an inert gas such as nitrogen gas or be evacuated.

In the case where each of the opposite surfaces of the array substrate 2 and the sealing substrate 3 is flat, a spacer may be placed between the sealing substrate 3 and the array substrate 2. Alternatively, a later-mentioned partition insulating layer 50 may be used as a spacer.

The array substrate 2 includes an insulating substrate 10 such as a glass substrate. On the transparent substrate 10, pixels are arranged in a matrix form.

Each pixel includes a pixel circuit and an organic EL element 40. Note that the organic EL elements 40 are collectively depicted as a layer 40G.

The pixel circuit includes, for example, a drive control element (not shown) and an output control switch 20 connected in series with the organic EL element 40 between a pair of power supply terminals, and a pixel switch (not shown). The drive control element has a control terminal connected to a video signal line (not shown) via the pixel switch and outputs a current, whose magnitude corresponds to a video signal supplied from the video signal line, to the organic EL element 40 via the output control switch 20. A control terminal of the pixel switch is connected to a scan signal line (not shown), and a switching operation of the control switch is controlled by a scan signal supplied from the scan signal line. Note that other structures can be employed for the pixels.

On the substrate 10, as an undercoat layer 12, for example, an SiNₓ layer and an SiOₓ layer are arranged in this order. A semiconductor layer 13 such as a polysilicon layer in which a channel, source and drain are formed, a gate insulator 14 which can be formed with use of, for example, TEOS (tetraethyl orthosilicate), and a gate electrode 15 made of, for example, MoW, are arranged in this order on the undercoat layer 12, and these layers form a top gate-type thin film transistor (referred to as a TFT hereinafter). In this example, the TFTs are used as TFTs of the pixel switch, output control switch 20 and drive control element. Further, on the gate insulator 14, scan signal lines (not shown) which can be formed in the same step as that for the gate electrode 15 are arranged.

An interlayer insulating film 17 made of, for example, SiOₓ which is deposited by a plasma CVD method, covers the gate insulator 14 and gate electrode 15. Source and drain electrodes 21 are arranged on the interlayer insulating film 17, and they are buried in a passivation film 18 made of, for example, SiNₓ. The source and drain electrodes 21 have, for example, a three-layer structure of Mo/Al/Mo, and electrically connected to the source and drain of the TFT via contact holes formed in the interlayer insulating film 17. Further, on the interlayer insulating film 17, video signal lines (not shown) which can be formed in the same step as that for the source and drain electrodes 21 are arranged.

A flattening layer 19 is formed on the passivation film 18. Reflection layers 70 are arranged on the flattening layer 19. A hard resin can be used as a material of the flattening layer 19, for example. A metal material such as Al, for example, can be used as a material of the reflection layer 70.

The flattening layer 19 and the reflection layer 70 are covered with an outcoupling layer 30. Here, as an example, the outcoupling layer 30 includes a first portion 31 and second portions 32 dispersed therein. The first portion 31 has light-transmission property, and the second portions 32 are different in optical property such as refractive index from the first portion 31.

On the outcoupling layer 30, first electrodes 41 with light-transmission property are arranged spaced apart from one another. Each first electrode 41 faces the reflection layer 70. In addition, each first electrode 41 is connected to a drain electrode 21 via through-holes formed in the passivation film 18, the flattening layer 19, and the outcoupling layer 30.

The first electrode 41 is an anode in this example. As a material of the first electrode 41, for example, a transparent conductive oxide such as an ITO (indium tin oxide) can be used.

A partition insulating layer 50 is placed on the outcoupling layer 30. In the partition insulating layer 50, through-holes are formed at positions corresponding to the first electrodes 41. The partition insulating layer 50 is an organic insulating layer, for example, and can be formed by using a photolithography technique.

An organic layer 42 including a light-emitting layer is placed on each first electrode 41 which is exposed to a space in the through-hole of the partition insulating layer 50. The light-emitting layer is a thin film containing a luminescent organic compound which can generate a color of, for example, red, green or blue. The organic layer 42 can further include a layer other than the light-emitting layer. For example, the organic layer 42 can further include a buffer layer which serves to mediate the injection of holes from the first electrode 41 into the emitting layer. The organic layer 42 can further contain a hole transporting layer, a hole blocking layer, an electron transporting layer, an electron injection layer, etc.

The partition insulating layer 50 and the organic layer 42 are covered with a second electrode 43 with light-transmission property. The second electrode 43 is a cathode which is continuously formed and common to all pixels. The second electrode 43 is electrically connected to an electrode wiring, the electrode wiring being formed on the layer on which video signal lines are formed, via contact holes (not shown) formed in the passivation film 18, the flattening layer 19, the outcoupling layer 30, and the partition insulating layer 50. Each organic EL element 40 includes the first electrode 41, organic layer 42 and second electrode 43.

As described above, in the organic EL display 1, the outcoupling layer 30 is placed adjacent to the organic EL element 40. When such a structure is employed, as described below, the light emitted by the light emitting layer of the organic EL element 40 can be extracted from the organic EL element 40 with higher efficiency.

A portion of the light components emitted by the light emitting layer propagates in an in-plane direction while repeating reflection (reflection or total reflection) in a layered structure of the first electrode 41 and the organic layer 42 or in a layered structure of the first electrode 41, the organic layer 42, and the second electrode 43. The light components propagating in the in-plane direction cannot be extracted from the layered structure (hereinafter referred to as a waveguide layer) if an incident angle on a main surface of the waveguide layer is great.

When the outcoupling layer 30 is placed near the organic EL element 40, a direction of the light emitted by the light emitting layer can be changed. Thus, it becomes possible to extract the light components emitted by the light emitting layer from the organic EL element 40 with higher efficiency.

As described above, when the outcoupling layer 30 is used, luminous efficiency of the organic EL element 1 can be improved. However, in a top emission organic EL display employing a sealing substrate 3, even if light is extracted from the organic EL element 40 with high efficiency, light emitted by the emitting layer cannot be effectively utilized for display unless the light is extracted from the sealing substrate 3 to the front side thereof with high efficiency.

Therefore, in the present embodiment, the organic EL display 1 is designed as follows. That is, a distance d from each element portion of the array substrate 2 corresponding to the organic EL element 40 to the sealing substrate 3 is set at a sufficiently large value. A further detailed description will be given here.

When the light emitted by the light emitting layer is incident on an interface between the organic EL element 40 and its upper space at an incident angle greater than a critical angle, evanescent wave which is near-field light is generated in the above-described upper space.

In the case where the distance d is short, the evanescent wave is converted to propagation light on an interface between the upper space of the organic EL element 40 and the sealing substrate 3. That is, the light incident on the interface between the organic EL element 40 and the upper space at an incidence angle greater than the critical angle enters the sealing substrate 3 without being totally reflected by the interface. At least a portion of this light is incident on the front surface of the sealing substrate 3 at an incidence angle greater than the critical angle, so that it cannot be extracted from the sealing substrate 3 to the front side thereof. For such reasons, in the case where the distance d is short, even if light has been extracted from the organic EL element 40 with high efficiency, the light cannot be extracted from the sealing substrate 3 to the front side thereof with high efficiency.

In contrast, in the case where the distance d is sufficiently long (in the case where the distance d is longer than the evanescent wave penetration depth), conversion from the propagation light to the evanescent wave and its reverse conversion occur on the same interface. In other words, of the light emitted by the emitting layer of the organic EL element 40, the light components incident on the interface between the organic EL element 40 and its upper space at an incidence angle greater than the critical angle is totally reflected by the interface.

The traveling direction of the totally reflected light is changed by the outcoupling layer 30. Therefore, the light extracted from the organic EL element 40 to the upper space is incident on the sealing substrate 3 at a relatively small incidence angle. Therefore, almost all of the light components incident on the sealing substrate 3 is extracted from the organic EL display 1 without being totally reflected by its front surface. Therefore, when the distance d is sufficiently long, it becomes possible to efficiently utilize the light emitted by the light emitting layer for a display.

In the meantime, assuming a case in which a refractive index of a waveguide layer is n_{EL}, a refractive index of an upper space of the waveguide layer is 1, and light having wavelength λ is made incident on an interface between the waveguide layer and its upper space at an incidence angle θ_{EL} greater than a critical angle, an energy E(0) of an evanescent wave on the interface, a distance z (>0) from the interface, and an energy E(0) of the evanescent wave at a position spaced apart from the interface by the distance z meets a relationship shown in the following equation.

$$E ( z ) = E ( 0 ) \times exp ( - \frac{4 π \sqrt{{n}_{EL}^{2} {sin}^{2} {θ}_{EL} - 1}}{λ} z )$$

As is evident from the above equation, the energy E(z) of the evanescent wave generated on a certain interface is exponentially reduced according to the distance z from the interface.

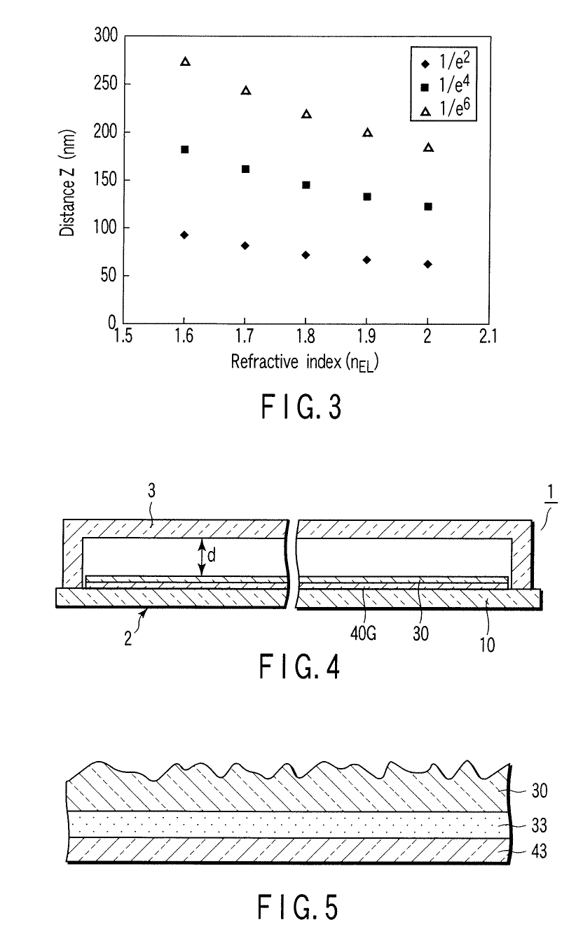

FIG. 3 is a graph showing an example of a relationship between a refractive index of a waveguide layer and an evanescent wave penetration depth. In the figure, the abscissa indicates a refractive index n_{EL} of the waveguide layer, and the ordinate indicates a distance z.

All the data shown in FIG. 3 is obtained by using the above equation. Specifically, the incident angle θ_{EL} is defined as 60°, and a wavelength λ is defined as 550 nm. In FIG. 3, the data labeled as “1/e²” indicates a distance z at which a ratio E(x)/E(0) is decreased to 1/e², the data labeled as “1/e⁴” indicates a distance z at which the ratio E(x)/E(0) is decreased to 1/e⁴, and the data labeled as “1/e⁶” indicates a distance z at which the ratio E(x)/E(0) is decreased to 1/e⁶.

The evanescent wave penetration depth generally means a distance z at which the ratio E(z)/E(0) decreases to 1/e². As shown in FIG. 3, the penetration depth is less than 100 nm. Therefore, when the distance d from each element portion to the sealing substrate 3 is defined as about 100 nm or more, it is believed that an evanescent wave can be sufficiently prevented from being converted into propagation light on an interface between the upper space of the waveguide layer and the sealing substrate 3. In addition, as is evident from FIG. 3, this effect becomes more advantageous by setting the distance d to 200 nm or more, and is further more advantageous by setting the distance d to about 300 nm or more.

The distance d may be set to about 3 μm or more. In this case, display unevenness due to interference is hardly visualized. The distance d may be set to about 3 mm or less. When the distance d is increased, a mechanical strength of the organic EL display 1 may be reduced.

Although a light scattering layer has been exemplified as an outcoupling layer 30 in the first embodiment, the outcoupling layer 30 may be a diffraction grating. In addition, between the outcoupling layer 30 and the first electrode 41, a light-transmitting layer which is thinner than the evanescent wave penetration depth may be placed as a flattening layer.

A second embodiment of the present invention will be described here.

FIG. 4 is a partial cross section schematically showing an organic EL display according to the second embodiment of the present invention. In FIG. 4, the organic EL display 1 is illustrated such that its display surface, that is, the front surface, faces upwardly and the back surface faces downwardly.

The organic EL display 1 has a structure similar to the organic EL display 1 shown in FIGS. 1 and 2 except that the outcoupling layer 30 is placed on a layer 40G which the organic EL elements 40 form. In a case where such a structure is employed, effects similar to those described in the first embodiment can be attained by setting the distance d from each element portion to the sealing substrate 3 in the same manner as described above.

In addition, the structure in which the outcoupling layer 30 is placed above the organic EL elements 40 makes it possible to eliminate the steps such as flattening and patterning the outcoupling layer 30.

In the present embodiment, a variety of structures can be employed for the outcoupling layer 30.

FIGS. 5 to 9 are sectional views each schematically showing an example of an outcoupling layer which can be used in the organic EL display of FIG. 4.

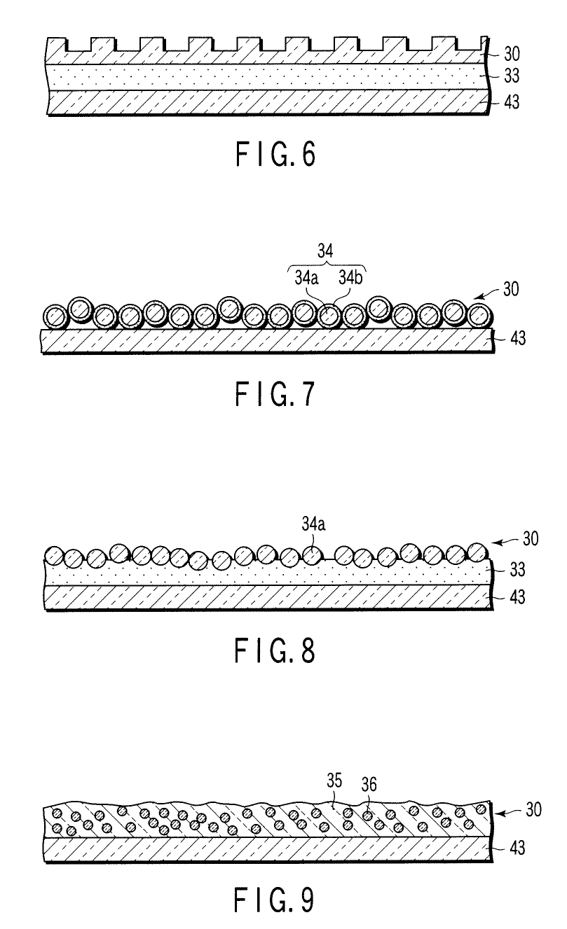

The outcoupling layer 30 shown in FIG. 5 is a light-transmitting layer having a main surface which is provided with randomly arranged recesses and/or protrusions. The outcoupling layer 30 makes it possible to extract light from the waveguide layer by light-scattering. On the other hand, the outcoupling layer 30 shown in FIG. 6 is a light-transmitting layer having a main surface which is provided with regularly arranged recesses and/or protrusions. The outcoupling layer 30 makes it possible to extract light from the waveguide layer by diffraction.

The outcoupling layer 30 shown in FIGS. 5 and 6 is, for example, a resin sheet or a resin film which can be handled by itself. In this case, the outcoupling layer 30 is fixed on a second electrode 43 by means of an adhesive layer 33, for example. The thickness of the adhesive layer 33 is 20 μm or more in general. Thus, even if irregularities occur on a surface of the second electrode 43, a gap is prevented from being generated between the adhesive layer 33 and the second electrode 41.

The outcoupling layer 30 shown in FIG. 7 includes light-transmitting particles 34 placed on the second electrode 43. The light-transmitting particles 34 are formed by coating transparent particles 34a with an adhesive 34b. The adhesive 34b bonds the transparent particles 34a together and bonds the transparent particles 34a to the second electrode 43. The outcoupling layer 30 shown in FIG. 7 can be formed by distributing the light-transmitting particles 34 over the second electrode 43 by wet or dry process. The outcoupling layer 30 shown in FIG. 8 is formed by distributing transparent particles 34a over an adhesive layer 33 by wet or dry process. The outcoupling layer 30 shown in FIGS. 7 and 8 makes it possible to extract light from the waveguide layer by light-scattering.

The outcoupling layer 30 shown in FIG. 9 is a light-scattering layer which includes a light-transmitting resin 35 and particles 36 dispersed therein. The particles 36 are different in optical property such as refractive index from the light-transmitting resin 35. The outcoupling layer 30 can be formed, for example, by coating the second electrode 43 with a coating solution which contains the particles 36 and a material for the light-transmitting resin 35 and curing the obtained coating film. Note that the material for the light-transmitting resin 35 is the one which can be cured at a temperature equal to or lower than the glass transition temperature of the organic layer 42.

In the outcoupling layer 30 of FIGS. 7 and 9, a material higher in refractive index than the waveguide layer such as TiO₂ or ZrO₂ may be used for the light-transmitting particles 34a and the particles 36. In this case, higher outcoupling efficiency can be achieved as compared with the case where a resin having a refractive index of about 1.5 is used.

In the case where the outcoupling layer 30 of FIGS. 5 and 9 is used, the thickness of a physically and chemically stable conductor layer which the second electrode 43 includes, for example, an ITO layer may be set to 10 nm or more in order to prevent a component contained in an adhesive or resin from being diffused into the organic layer 42. In this case, the thickness of the above-described conductor layer may be set to 40 nm or more in consideration of a pin-hole or the like.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A top emission organic EL display comprising:
an array substrate comprising an insulating substrate, organic EL elements which are arranged on a main surface of the insulating substrate, and an outcoupling layer which extracts light components propagating in in-plane direction while causing multiple-beam interference from the organic EL element to make the light components travel in front of the organic EL element; and
a sealing substrate facing and spaced apart from the organic EL elements,
wherein the display forms an enclosed space filled with an inert gas or evacuated between the sealing substrate and an element portion of the array substrate corresponding to the organic EL element, and
wherein a distance between the element portion and the sealing substrate is 100 nm or longer.

2. The display according to claim 1, wherein the distance between the element portion and the sealing substrate is 200 nm or longer.

3. The display according to claim 1, wherein the distance between the element portion and the sealing substrate is 300 nm or longer.

4. The display according to claim 1, wherein the distance between the element portion and the sealing substrate is 3 μm or longer.

5. The display according to claim 1, wherein the distance between the element portion and the sealing substrate is 3 mm or shorter.

6. The display according to claim 2, wherein the distance between the element portion and the sealing substrate is 3 mm or shorter.

7. The display according to claim 3, wherein the distance between the element portion and the sealing substrate is 3 mm or shorter.

8. The display according to claim 4, wherein the distance between the element portion and the sealing substrate is 3 mm or shorter.

9. The display according to claim 1, wherein the outcoupling layer is interposed between the insulating substrate and the organic EL elements.

10. The display according to claim 1, wherein the outcoupling layer covers the organic EL elements.
